(19) United States
(12) Patent Application Publication
(10) Pub. No.: US 2026/0367185 A1
(43) Pub. Date: Nov. 19, 2026

(54) SYSTEM AND METHOD FOR DIGITAL TWIN-BASED HEALTH AND FAULT MONITORING FOR POWER ELECTRONICS SYSTEMS

(71) Applicant: THE RESEARCH FOUNDATION FOR THE STATE UNIVERSITY OF NEW YORK, Albany, NY (US)

(72) Inventors: Austin ZHOU, Corona, NY (US); Fang LUO, Stony Brook, NY (US); Kushan CHOKSI, Stony Brook, NY (US); Abdul Basit MIRZA, Stony Brook, NY (US); Masayuki HIJIKATA, Huntington Station, NY (US)

(21) Appl. No.: 19/487,861

(22) PCT Filed: May 24, 2024
(86) PCT No.: PCT/US2024/030954

§ 371 Date: Nov. 25, 2025

Related U.S. Application Data
(60) Provisional application No. 63/504,279, filed on May 25, 2023.
(60) Provisional application No. 63/636,463, filed on Apr. 19, 2024.

(51) Int. Cl. G01R 31/56; G01R 19/25; G05B 23/02; H02M 1/00; H02M 3/157; H02M 3/158

(52) U.S. Cl. CPC G01R 31/56; G01R 19/2509; G01R 19/2516; G05B 23/0243; H02M 1/0009; H02M 1/0025; H02M 3/157; H02M 3/1586

(57) ABSTRACT

A digital twin which may be used to determine the health of a power converter, a method for using the digital twin and a health monitoring system is provided. The digital twin may comprise a plurality of state equations representing circuit components of the power converter and at least one associated value for each component. Each state equation is capable of representing the circuit components for a defined power converter topology and related variants. The digital twin also has a self-evolving monitoring function. The self-evolving monitoring function has adjustable model parameters, an adjustable threshold and adjustable determination parameters. The adjustable model parameters may include weights for combining determined voltage and determined current, respectively. The adjustable determination parameters may be used to determine sets of values for the components for predicting the voltage and current, respectively. The method/system is able to, in real-time, determine component degradation in the power converter.

### CROSS REFERENCE TO RELATED APPLICATION

The present application claims benefit of U.S. Provisional Application No. 63/504,279, filed on May 25, 2023 and U.S. Provisional Application No. 63/636,463 filed Apr. 19, 2024, all of the contents of which are incorporated herein by reference.

### GOVERNMENT SUPPORT

This invention was made with government support under DE-AC05-00OR22725 awarded by the Department of Energy. The government has certain rights in the invention.

### FIELD OF THE DISCLOSURE

This disclosure relates to monitoring the health of components within power electronics systems and fault detection. This disclosure relates to computer systems with self-evolving digital twin which may adapt to usage conditions including errors in sensing hardware.

### BACKGROUND

Power electronic systems, such as power converter, are comprised of numerous discrete components. These components include inductors, capacitors and semiconductor devices. The components also include the printed circuit board (PCB), connectors and solder. During operation, such as after long-term use, these components degrade and become weak to withstand normal electrical and thermal stress. This degradation has become more important due to the performance gain achieved from faster switching of wide band-gap devices (WBG).

These power converters are used in most electronics ranging from electric vehicles. Renewable energy (RE) power generation and transportation technologies. This wide-spread use has created a massive demand for converters with high-reliability and low to no failure rates, such as component failure in use.

To ensure the high-reliability, condition monitoring, fault monitoring and lifetime estimation is needed. High switching frequency and higher dV/dt introduce second-order phenomena which heavily impact sensor integrity and embedded system communication and operation. The sampling frequency of sensors needed for such monitoring is also going in a higher range from MHz to GHz. This makes developing an accurate, robust, and reliable condition-monitoring algorithm a challenging task.

The condition monitoring may be on a system-level basis or component-level basis. On state voltages, on state resistance, threshold voltages, Miller plateaus, case temperatures, thermal resistance and other thermal parameters are major health indicators for any semiconductor switch health monitoring. Similarly, capacitor discharge voltage and current ripple attribute as health indicators of capacitor health. Furthermore, inductor current ripple for inductor health monitoring. On-state resistance of power semiconductor impacts frequency-response and harmonics of the power converter.

Component-level monitoring is typically costly and invasive as it needs separate circuitry and hardware for the individual condition monitoring,

Certain “off-line” methods have been proposed for condition monitoring including employing artificial intelligence and machine learning such as artificial neural network. However, these offline approaches do not provide a real-time analysis.

A known system has used a digital twin (DT) to provide a virtual representation of its physical counterpart. This DT mirrors the circuits behavior using live data capture from the sensors. However, this known system using DT had fixed parameters which do not account for operating condition for environment or the performance of the sensors.

### SUMMARY

Accordingly, disclosed is a digital twin which may be used to determine the health of a power converter and a method for using the digital twin. The digital twin may comprise a plurality of state equations representing circuit components of the power converter and at least one associated value for each component. Each state equation is capable of representing the circuit components for a defined power converter topology and related variants. The digital twin also has a self-evolving monitoring function. The method comprises receiving a sensed value from one or more sensors, respectively. The one or more sensors may be a voltage sensor and/or a current sensor for sensing voltage and/or current within the power converter, respectively. The method further comprises defining at least one set of values for the components of the power converter in the digital twin using the self-evolving monitoring function, determining, using the self-evolving monitoring function, digital twin voltage and/or current corresponding to the sensed voltage and/or current respectively, based on each defined set of values, comparing, using the self-evolving monitoring function, each determined digital twin voltage and/or current, with values obtained from the corresponding sensors, determining, using the self-evolving monitoring function, a difference between each determined digital twin voltage and/or current and values obtained from the corresponding sensors using adjustable model parameters of the self-evolving monitoring function and outputting one of the at least one set of values as the health of the power converter when the determined difference is less than an adjustable threshold of the self-evolving monitoring function. When the difference is greater than the adjustable threshold, the method repeats, the defining, the determining, the comparing, the determining and outputting. These features are repeated using new at least one set of values for the components of the power converter in the digital twin until a condition is met. The new at least one set of values are based on adjustable determination parameters of the self-evolving monitoring function.

In an aspect of the disclosure, a subset the values in each set may be randomly determined. In some aspects, certain values may be calculated in each set.

In an aspect of the disclosure, the method may further comprise compensating the received sensed values from one or more sensors based on an error detection to determine the values obtained from the corresponding sensors or the digital twin determined current and/or voltage.

In an aspect of the disclosure, the adjustable model parameters may include summation weights used to add the determined output voltage and the determined current(s). The summations weights may be individually adjustable based on error detection with respect to the sensors.

In an aspect of the disclosure, the adjustable determination parameters may be individually adjustable based on error detection. The error detection may include determining at least quantization error, DC offset error and synchronization error.

In an aspect of the disclosure, the adjustable determination parameters may include a learning rate and weights for local and global best.

In an aspect of the disclosure, the adjustable threshold may be set based on operating conditions for the power converter such as at least one of a maximum output voltage or maximum inductor current.

In an aspect of the disclosure, the adjustable threshold may be initialized during a calibration period.

In an aspect of the disclosure, the circuit components may include switches and inductors. The at least one value may include Resistanceₒₙ, inductance and inductor resistance.

In an aspect of the disclosure, the method may comprise determining the Resistanceₒₙ and inductor resistance independently. The inductor resistance may be predicted during inductor discharging and the Resistanceₒₙ may be predicted during inductor charging.

In an aspect of the disclosure, the plurality of state equations and the self-evolving monitoring function may be stored in a memory and executable by a processor embedded with a housing of the power converter.

In an aspect of the disclosure, the outputting may comprise transmitting a packet to an external device. In other aspects, the outputting may also comprise causing a display on the external device to display the health of the power converter.

In an aspect of the disclosure, when the condition is met and the difference is still greater than the adjustable threshold, the packet may include a set of values with the smallest difference and the determined difference. Otherwise, when the difference is smaller than the adjustable threshold, the packet may include the set of values without the determined difference.

In an aspect of the disclosure, the values for different component types in the set included in the packet may be separately displayed on the display. The display may show a change in the values over time.

In an aspect of the disclosure, the method may further comprise determining a fault condition based on the change in a value over time and displaying indication based on the determination.

In an aspect of the disclosure, the power converter may be a multi-phase boost converter.

Also disclosed is a health monitoring system for a power converter. The health monitoring system comprises a memory, a voltage sensor, a current sensor and a processor. The memory stores a digital twin comprising a plurality of state equations representing circuit components of a power converter and at least one associated value for each component. Each state equation may be capable of representing the circuit components for a defined power converter topology and related variants. The memory may further store a self-evolving monitoring function having adjustable model parameters, adjustable threshold and adjustable determination parameters. The adjustable model parameters may include weights for combining determined voltage and determined current, respectively. The adjustable determination parameters may be used to determine sets of values for the components for predicting the voltage and current, respectively. The voltage sensor is configured to detect a voltage of the power converter and the current sensor is configured to detect a current within the power converter. The processor is configured to receive the detected voltage from the voltage sensor and the detected current from the current sensor, define at least one set of values for the components of the power converter in the digital twin using the self-evolving monitoring function, determine, using the self-evolving monitoring function, digital twin voltage and current corresponding to the sensed voltage and current respectively, based on each defined set of values, compare, using the self-evolving monitoring function, each determined digital twin voltage and current, with values obtained from the corresponding sensors, determine, using the self-evolving monitoring function, a difference between each determined digital twin voltage and current and values obtained from the corresponding sensors using the adjustable model parameters of the self-evolving monitoring function and output one of the at least one set of values as the health of the power converter when the determined difference is less than the adjustable threshold of the self-evolving monitoring function. In an aspect of the disclosure, when the difference is greater than the adjustable threshold, the processor is configured to repeat the defining, determining, comparing, and determining using new at least one set of values for the components of the power converter in the digital twin until a condition is met. The new at least one set of values may be based on the adjustable determination parameters of the self-evolving monitoring function.

In an aspect of the disclosure, the memory may be on-board memory co-located with the power converter. In an aspect of the disclosure, the system may further comprise a communication interface configured to transmit the one of the at least one set of values as the health of the power converter or a set of values having a smallest difference when the condition is met.

### BRIEF DESCRIPTION OF THE DRAWINGS

The patent or application file contains at least one drawing executed in color. Copies of this paper or patent application publication with color drawing(s) will be provided by the Office upon request and payment of the necessary fee.

FIG. 1A illustrates an example of a power converter monitoring system in accordance with aspects of the disclosure;

FIG. 1B illustrates an example of a power converter monitoring system in accordance with aspects of the disclosure;

FIG. 2 illustrates an example of a self-evolving digital twin in accordance with aspects of the disclosure;

FIG. 3 illustrates an example of a self-evolving monitoring function in accordance with aspects of the disclosure;

FIG. 4 illustrates an example of a power converter topology (and specifically a model thereof) which may be monitored in accordance with aspects of the disclosure;

FIGS. 5A-5C illustrate examples of related variants of the power converter (showing their models) illustrated in FIG. 4;

FIG. 6 illustrates an example of a control circuitry model in accordance with aspects of the disclosure;

FIG. 7 illustrates an example of sampling circuitry model in accordance with aspects of the disclosure;

FIG. 8 illustrates an example of a method for determining the initial operating conditions and initial threshold in accordance with aspects of the disclosure;

FIG. 9 illustrates an example of a method of the self-evolving monitoring function in accordance with aspects of the disclosure;

FIG. 10A illustrates an example of the error calibration in accordance with aspects of the disclosure;

FIG. 10B illustrates an example of the error compensation and determining the adjustable parameters in accordance with aspects of the disclosure;

FIGS. 11A-11E illustrates examples of errors and the impact thereon the prediction; and FIG. 12 illustrates an example of a dashboard in accordance with aspects of the disclosure.

### DETAILED DESCRIPTION

Aspects of the disclosure provide systems and methods for monitoring the health of power electronic systems such as a power converter using a self-evolving digital twin. The self-evolving digital twin has a self-evolving monitoring function which is used to predict values of circuit components (including parasitic) within the power converter from candidate values. The candidate values may comprise multiple sets of candidate values for the components (such as a swarm). The self-evolving monitoring function predicts the component values by predicting values corresponding to real-time sensed values and attempts to match the predicted values with the sensed values such as within an adjustable threshold (difference). In an aspect of the disclosure, the sensed values may be topology specific. For example, the sensed values may be an output voltage of the power converter and current across an inductor. This self-evolving monitoring function may be used for diagnostic, maintenance, lifetime assessment, and cyber secured interfaced control.

The predicted values of the components include the parasitics. Parasitics are electrical properties are inherently in an electrical component, but which are not desirable for it to have the intended purpose of the electrical component. For example, an inductor has inductance (its intended purposes) but also has resistance. A semiconductor device, such as a switch, has an on-state resistance Ron.

When there is a match, the component values used for the prediction become the predicted component values which are output as the health of the power converter.

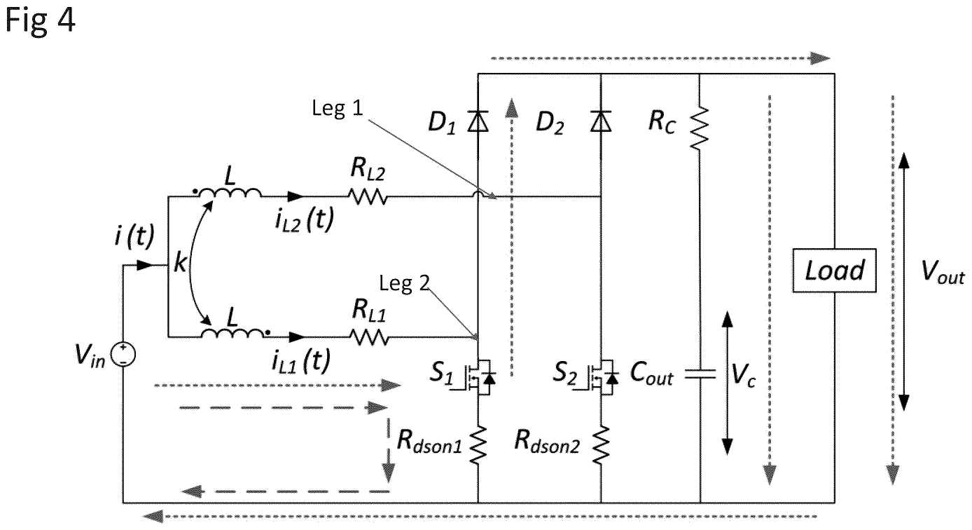

The systems and methods described herein may be used to predict the component values for different power converter topologies. The power converter may be a DC-to-DC converter or DC-to-AC converter, vice versa, or a combination thereof. For example, the power converter may be multiple stages such as a DC-DC stage and a DC-AC stage (e.g., four-phase interleaved DC-DC boost converter and a split-phase DC-AC inverter). One example, topology is shown in FIG. 4. The power converter shown is a boast converter with its parasitic (model 102). It has two legs (Leg 1 and Leg 2). This power converter is interleaved (also referred to as two-phase interleaved boost converter). The inductors L are reversed coupled. In other aspects, the power converter may be an AC-to-AC converter. The converter may provide a single-phase AC or multiple phase AC.

However, the topology is not limited to boost converters and may also a buck or flyback. Additionally, a boost converter is not limited to the example configuration but may including “Related Variants”. The phrase “Related Variants” means different number of legs, different inductor coupling and interleaving. For example, a boost DC-to-DC may have two legs, four legs, etc. (N-legs) A boost DC-to-DC power converter may have all inductors coupled, alternate inductor channels coupled, alternate inductor channels reversed coupled, half of the inductor channels coupled, etc. The power converter may operate in a discontinuous conduction mode (DCM) or a Continuous conduction mode (CCM). The power converter may have any power capacity.

The power converter may be incorporated into power systems such as in vehicles, both commercial and military. The vehicles may be electric vehicles. The power converters may be incorporate into renewable energy power generation systems and other industrial applications.

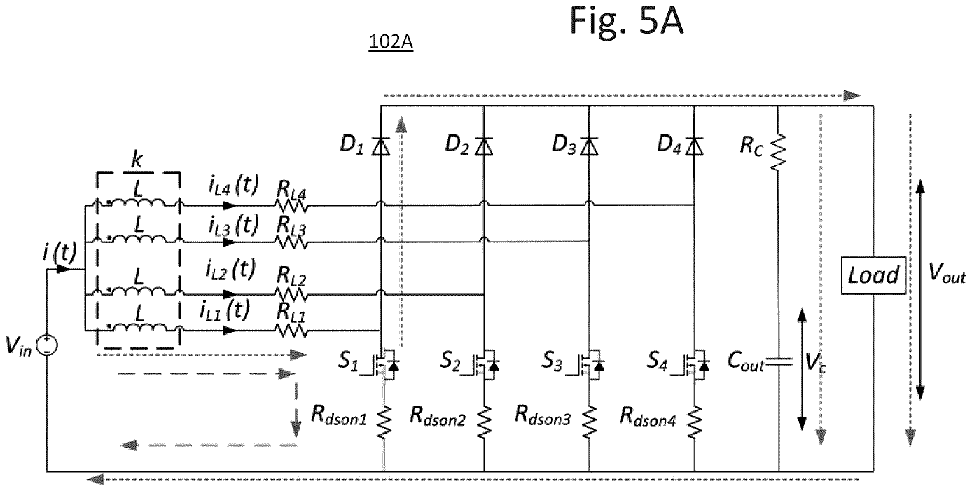

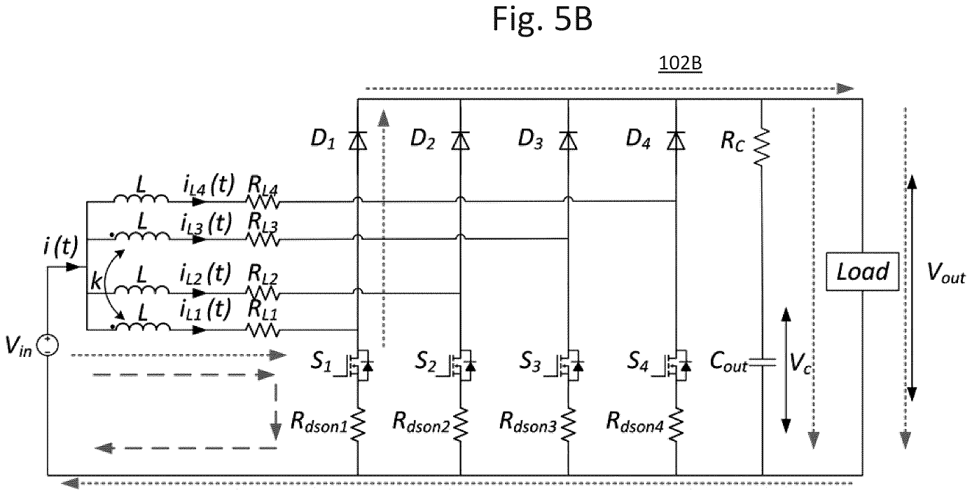

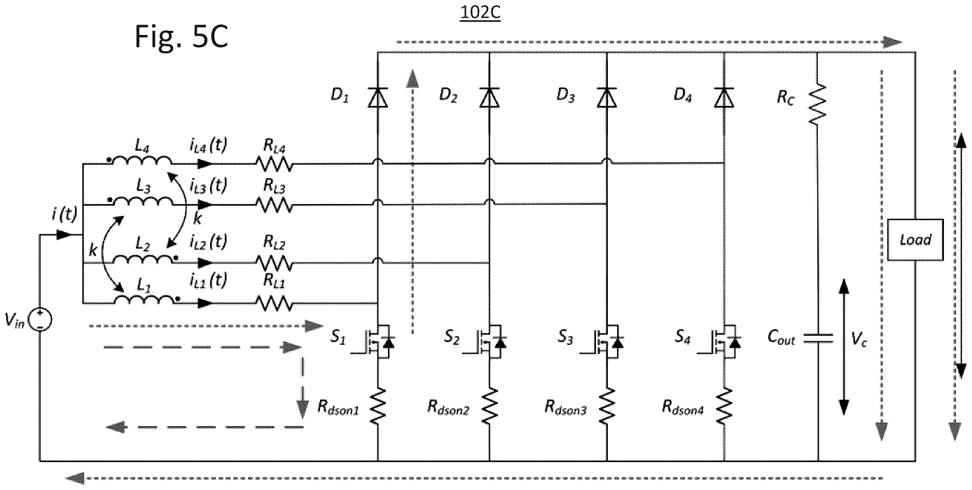

The Related Variants illustrated in FIGS. 5A-5B all have four legs. However, the three example power converters (figures shown parasitic and other circuit model parameters) have different coupling strategies. FIGS. 5A-5C show models 102A-102C for the Related Variants. For example, the power converter (model) 102A (FIG. 5A) has all of the inductor channels coupled. The power converter (model) 102B (FIG. 5B) has two channels coupled (channel 2 and channel 4). The power converter 102C (model) (FIG. 5C) has alternate channels reverse coupled (channel 1 and channel 3) and (channel 2 and channel 4).

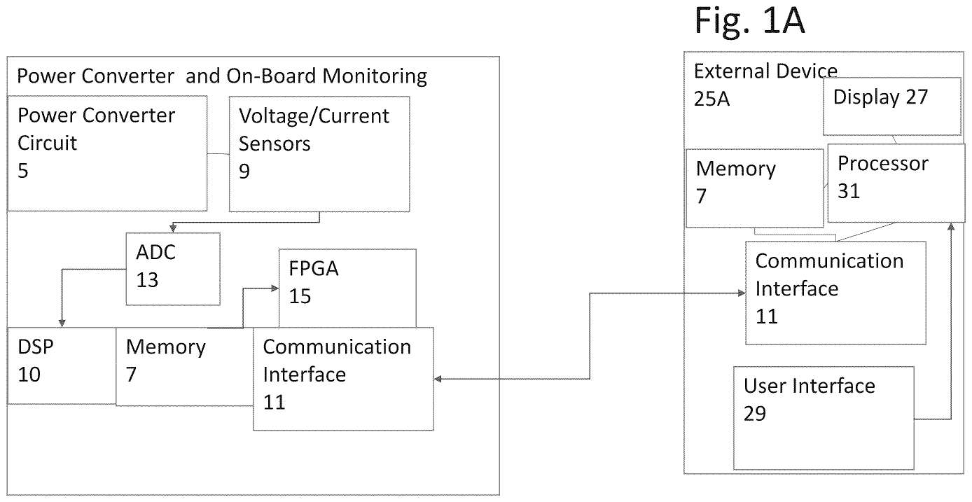

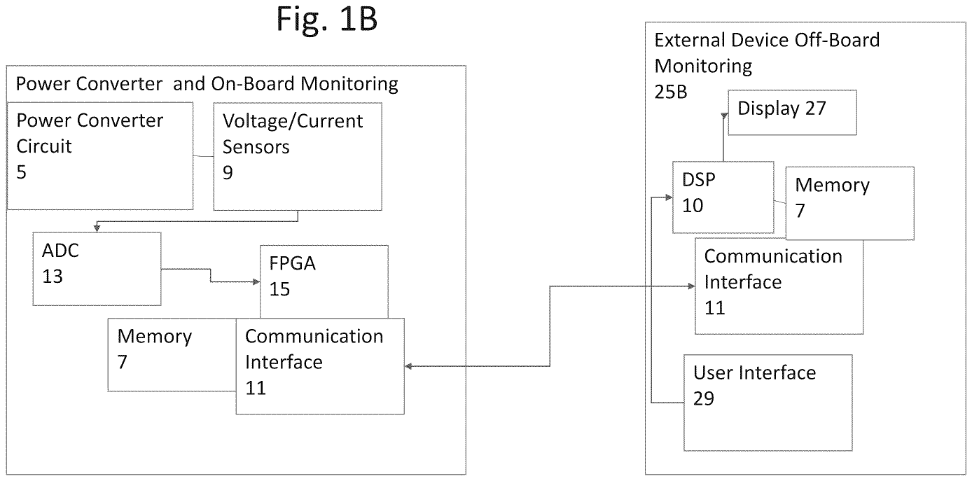

FIG. 1A illustrates a block diagram of a power converter monitoring system in accordance with aspects of the disclosure. Certain components of the monitoring system may be embedded, meaning that they are within the housing of the power converter system (also referred to herein as on-board) and some of the components of the monitoring system may be external such as in a remote device.

In an aspect of the disclosure, the system may comprise a microcontroller 10 (an example of a processor). The microcontroller may be a digital signal processor (DSP). The methods described herein may require a robust computational platform to carry out the data processing. The requirements may be based on the complexity of the topology of the power converter and components used in the power converter (such WBG semiconductors such as SiC), the specific self-evolving monitoring function 110, number of iterations in the function and number of candidates processed per iteration (such as swarm size). In an aspect of the disclosure, the microcontroller 10 may be a LAUNCHXL-F28379D microcontroller unit (MCU) from Texas Instrument. The core may be driven by a main clock up to 200 MHz. This microcontroller 10 (hereinafter “DSP 10”) has a dual-core. This microcontroller 10 may have a rating of at 800 mega instructions per second (MIPS), which is crucial because two standards can primarily measure the performance factor of the microcontroller: the clock frequency as well as the instruction rate.

As shown in FIG. 1A, the DSP 10 is on-board, however, in other aspects of the disclosure, such as shown in FIG. 1B, the DSP 10 may be located in the external device 25B. The clock frequency primarily affects the peripherals' operation speed, such as the ADC 13 (which will be described later), whereas the instruction rate affects the computational performance. In an aspect of the disclosure, the DSP 10 has a main clock frequency that is high enough to provide fast clocking to the peripherals.

However, the processor(s) used for the functionality described herein is not limited to a microcontroller and may be other processors such as a CPU or a GPU.

In an aspect of the disclosure, multiple DSP 10 (microcontrollers) may be included in the system and work in parallel to enable convergence of the predicted v. sensed values.

In an aspect of the disclosure, the system also comprises an analog to digital converter ADC 13. The ADC 13 is configured to sample the sensors 9 at a defined sample rate. The sample rate may be set based on the topology of the power converter and semiconductor element. For example, a silicon carbide (SiC) devices, can switch in the kHz range, which requires a high speed, ADC sampling in the MHz range. Other wide band gap semiconductor switches may even have a higher speed, requiring a higher sampling rate. In an aspect of the disclosure, the ADC oversamples, e.g., multiple samples per cycle. This is to ensure the correct cycle identification.

In an aspect of the disclosure, the ADC 13 may have multiple modules. For example, the ADC 13 may have two or more modules. In some aspects of the disclosure, there may be 4 onboard ADC 13. Each onboard module may be driven by a peripheral clock of the microcontroller 10. This enables a fast sampling rate. For example, the sampling rate may be up to 1.1MSPS with a resolution of 16 bits. The sampling rate may be different depending on the microcontroller used or other processors.

In an aspect of the disclosure, the system may also comprise a memory 7. The memory 7 may be included both on-board and in the external device 25A or 25B. The size of the memory may depend on whether the calculation(s) is/are performed on-board or in the external device 25B.

For example, when the DSP 10 is on-board, the on-board memory 7 may store the model of the power converter (circuitry) 102, state equations associated with the model 104, the self-evolving monitoring function 110 (with all of its parameters, such as weights, threshold, learning parameters, etc . . . ), sensor readings, candidate sets for the values of the components, predictions, differences, etc.) and other models. The external device 25A memory may store the calculated values determined by the self-evolving monitoring function 110 such as for a dashboard which is viewable on a display 27. When the DSP 10 is in the external device 25B, the on-board memory 7 may store the sensed values from the sensors 9.

The specific information stored in the memory 7 may be based on the self-evolving monitoring function 110. Given the amount of data stored, the memory may be a specific size. The memory 7 may be configured using stack memory. In some aspects, a custom linker file may be used to allocate a set space for the stack to avoid memory leaking.

In an aspect of the disclosure, the DSP 10 implements an interrupt driven operation where every interrupt service routine (ISR) relies on the stack memory to store data from the previous state to avoid confusion when the program counter returns to the main function.

The sensors 9 may be voltage sensors and/or current sensors. The number of sensors and placement thereof may be topology and Related Variant dependent. For example, there may be one voltage sensor and two current sensors for a boost power converter with two phases legs as shown in the model depicted in FIG. 4, where the voltage sensor senses Vout and the current sensor senses inductor current I_{I.1}(t) and I_{I.2}(t). For four leg Related Variants (such as shown in FIGS. 5A-5C), there may be 5 sensors (one voltage sensor for Vout and four current sensors, one per leg). The accuracy of the monitoring system depends on a noise-free data acquisition from the sensors 9 (measure the state variables). In an aspect of the disclosure, the sensor 9 may have a high bandwidth to measure both DC and ripple current components. For example, the current sensors may be shunt current sensor available from Texas Instruments such as model no. AMC1302x series optically isolated amplifier. This series has a bandwidth of up to 800 kHz, which is greater than 10 times the expected switching frequency of the semiconductor devices (switches). Additionally, the voltage sensor may be an isolated differential amplifier available from Broadcom, such as model ACNT-H790-500E. In an aspect of the disclosure, a stretched SS0-8 package may be used to provide barrier isolation up to 7500 Vrms with 15Vns transient immunity. Since the sensors 9 may be connected to a circuit card, such as a control card, the sensors 9 may be shield. The shield may be grounded on both sides to provide external magnetic and electrical shielding.

The monitoring system may further comprise a communication interface 11. In some aspects of the disclosure, the communication interface 11 may be an onboard universal asynchronous receiver transmitter (UART) module. The UART module may utilize a two-wire bidirectional serial protocol that allows the on-board part of the system to broadcast to an external user interface (external device 25A/25B)

The UART communication may consist of an uplink and a downlink. The uplink allows any condition monitoring result computed on the DSP 10 to be transmitted to the device 25A at a second interval. The downlink may enable, an external device 25A to directly start and stop a power stage closed-loop control. In other aspects, instead of the uplink being used to transmit the condition monitoring results such as the predicted values, the sensed values may be transmitted using the UART communication to device 25B for the external DSP 10 to predict.

The communication interface 11 is not limited to UART and other wired or wireless interfaces may be used. Depending on the type of communication interface 11, a relay device may be used to relay data between the onboard components and the external device 25A or 25B. For example, an FTDI chip may be used. The FTDI chip may be available from Adafruit. This may converter the UART into a USB interface (connection).

The monitoring system may also have other processing such as the FPGA 15. The FPGA may be used if an external hierarchical control is used. The FPGA 15 may be a DE-0 Nano Cyclone IV FPGA available from Terasic. If needed, the DSP 10 and the FPGA 15 may communicate using an SPI link. In other aspects, the FPGA 15 may be used to share a computational load.

The system may also comprise auxiliary power, which may be supplied to the control card to power sensors, control circuitry and power gate drivers in a power converter. The DSP 10 and FPGA 15 may be on the same control card. The FPGA 15 may communicate with a PWM via fiber optic cables.

The on-board monitoring (such as the onboard DSP 10) may communicate with an external device 25A. This external device 25A may be a user terminal such as a personal computer (with a processor 31). The user terminal may also be a portable device such as a mobile terminal including a tablet, laptop or mobile phone. The external device 25A or 25B has a display 27 and a user interface 29. The user interface 29 may be a touch screen superposed on the display 27.

In an aspect of the disclosure, the on-board communication interface 11 may streams the predicted component values (set) as one single packet. The packet may be transmitted when the predicted and actual converge or after a maximum number of iterations as will be described. In an aspect of the disclosure, the adjusted model parameter such as threshold, weights and learning parameter may be included in this packet or as a separate packet. In some aspects of the disclosure, the transmitter converts the data from float point to hexadecimal. The packet length for transmission may be primarily determined by the total number of phases in the power converter circuit 5, which implies a proportional escalation in the overall transmission size and transmission time as the number of phases increases. To prevent data corruption, a header, and a footer may be inserted at the beginning and the end of the data packet, respectively, before each streaming.

The user interface 29 may be a graphic user interface (GUI). The GUI may interface with the communication interface 11. The GUI may show a time series of the predicted values for the electrical components of the power converter 5 (dashboard) such as shown in FIG. 12. In an aspect of the disclosure, the GUI may allow for data viewing of each condition monitoring channel (specific value) or a system-wise view. The dashboard may be customized to show one or more of the monitoring channels.

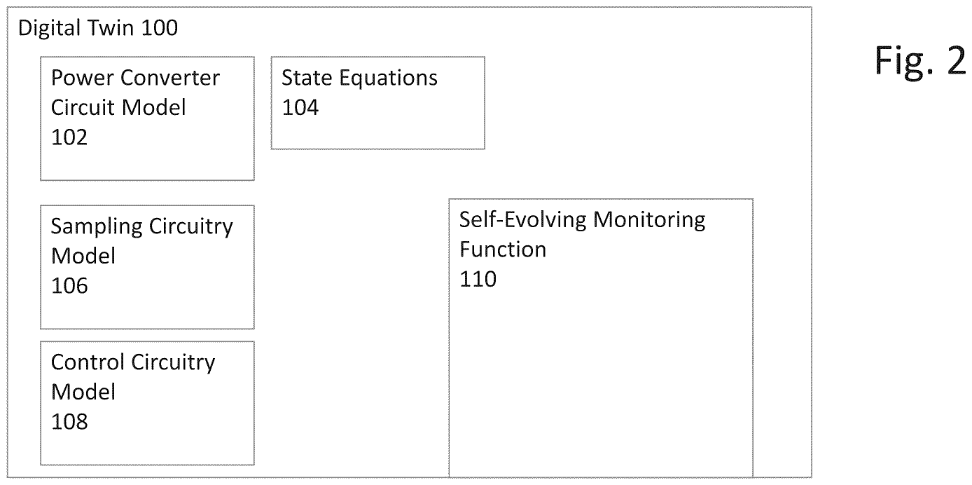

FIG. 2 illustrates an example of the digital twin 100 in accordance with aspects of the disclosure to mirror/replicate the physical power converter. The digital twin 100 may comprise a power converter circuit model 102 and state equations 104. FIG. 4 illustrates an example of the power converter circuit model 102 for the two-leg IBC with respect coupled inductors. I_{L1}(t) and I_{L2}(t) represent inductor channel currents. V_{c} represents the output capacitor voltage. R_{dson1} and R_{don2} represent parasitic resistance of the switches (on-state resistance). R_{L1} and R_{L2} represent the parasitic resistance of the coupled inductors. R_{c} represents the parasitic resistance of the output capacitor.

In an aspect of the disclose the state equations 104 (extended state space equations) may be generic for the topology and stored in memory 7 and subsequently may be customized for the specific Related Variant by adding or subtracting terms or adjusted for any coupling strategies. The state equations may be obtained from an RK 4^{th} order method. Eqs. 1-5 are generic for any boost converter, IBC, coupled IBC, reverse coupled IBC, operating in CCM or DCM modes of operation.

\dot{x}(t)=Ax(t)+Bu(t) (1)

$${H}_{m , n} = {\overline{s}}_{n} ( {Σ}_{{{i}_{1} = 1}_{{i}_{1} \neq n}}^{N} {\overline{s}}_{{i}_{1}} {k}_{{i}_{1} , n} + {Σ}_{{{{i}_{1} = 1}_{{i}_{1} \neq {i}_{2} \neq n}}_{{i}_{1} < {i}_{2}}}^{N} {Σ}_{{i}_{2} = 1}^{N} {\overline{s}}_{{i}_{1}} {\overline{s}}_{{i}_{2}} {k}_{{i}_{1} , n} {k}_{{i}_{2} , n} + \cdot + {Σ}_{{{{i}_{1} = 1}_{{i}_{1} \neq … {i}_{N - 1} \neq n}}_{{i}_{1} < … < {i}_{N - 1}}}^{N} … {Σ}_{{i}_{N - 1} = 1}^{N} {\overline{s}}_{{i}_{1}} {\overline{s}}_{{i}_{2}} … {\overline{s}}_{{i}_{N - 1}} {k}_{{i}_{1} , 1} {k}_{{i}_{2} , 1} … {k}_{{i}_{N - 1} , 1} ) \qquad ( 2 )$$

$$StateMatrix A = [ \begin{matrix}\frac{- 1}{{K}_{C}} [ {G}_{1} + {H}_{m , 1} P ] & \frac{- 1}{{K}_{C}} [ {G}_{2} + {H}_{m , 2} \frac{P}{k} ] & ⋯ & \cdot & {Σ}_{{{i}_{1} = 1}_{i \neq 1}}^{N} {\overline{s}}_{i} P + {\overline{s}}_{1} Pk \\ \frac{- 1}{{K}_{C}} [ {G}_{1} + {H}_{m , 1} \frac{P}{k} ] & \frac{- 1}{{K}_{C}} [ {G}_{2} + {H}_{m , 2} P ] & ⋯ & \cdot & {Σ}_{{{i}_{1} = 1}_{{i}_{1} \neq n}} {\overline{s}}_{i} P + {\overline{s}}_{2} Pk \\ ⋮ & ⋮ & ⋱ & ⋮ & ⋮ \\ \frac{{\overline{s}}_{1}}{C} [ \frac{R}{R + {R}_{C}} ] & \frac{{\overline{s}}_{2}}{C} [ \frac{R}{R + {R}_{C}} ] & ⋯ & \frac{{\overline{s}}_{N}}{C} [ \frac{R}{R + {R}_{C}} ] & \frac{- \overline{1}}{C} [ \frac{1}{R + {R}_{C}} ]\end{matrix} ] \qquad ( 3 )$$

$$InputMatrix B = [ \begin{matrix}\frac{1 + k}{{K}_{C}} & \frac{- 1}{{K}_{C}} ( {\overline{s}}_{1} k + {Σ}_{{{i}_{1} = 1}_{i \neq 1}}^{N} {\overline{s}}_{i} ) \\ \frac{1 + k}{{K}_{C}} & \frac{- 1}{{K}_{C}} ( {\overline{s}}_{2} k + {Σ}_{{{i}_{1} = 1}_{i \neq 2}}^{N} {\overline{s}}_{i} ) ) \\ ⋮ & ⋮ \\ \frac{1 + k}{{K}_{C}} & \frac{- 1}{{K}_{C}} ( {\overline{s}}_{N - 1} k + {Σ}_{{{i}_{1} = 1}_{i \neq N - 1}}^{N} {\overline{s}}_{i} ) \\ 0 & 0\end{matrix} ] \qquad ( 4 )$$

$$Coupling Matrix = [ \begin{matrix}1 & {k}_{1 , 2} & ⋯ & {k}_{1 , j} \\ {k}_{2 , 1} & 1 & ⋯ & {k}_{2 , j} \\ ⋮ & ⋮ & ⋱ & ⋮ \\ {k}_{i , 1} & {k}_{i , 2} & ⋯ & 1\end{matrix} ] \qquad ( 5 )$$

$$\dot{x} ( t ) = [ \begin{matrix}\frac{{di}_{1}}{dt} \\ \frac{{di}_{1}}{dt} \\ \cdot \\ \cdot \\ \frac{{di}_{N}}{dt} \\ \frac{{dv}_{C}}{dt}\end{matrix} ] , x ( t ) = [ \begin{matrix}{i}_{1} \\ {i}_{2} \\ \cdot \\ \cdot \\ {i}_{N} \\ {v}_{C}\end{matrix} ] , u ( t ) = [ \begin{matrix}{V}_{in} \\ {V}_{d}\end{matrix} ] \qquad ( 6 )$$

$$\begin{matrix}P = \frac{{RR}_{C}}{R + {R}_{C}} & ( 7 )\end{matrix} \qquad ( 7 )$$

$$\begin{matrix}{{G}_{i}}_{i ∈ ⌊ 1 , 2 , … , N ⌋} = {R}_{Li} + {s}_{i} {R}_{ONi} + {( {s}_{i} )}^{-} P & ( 8 )\end{matrix} \qquad ( 8 )$$

Variable Gi refers to the decoupled self-inductor states of any phase leg. Hm,n refers to the impact of other phases on to state variable of that phase leg. It shall be noted ki,j is coupling between ith and jth channel inductors. Also, sn or si refers to the switching state of MOSFET belonging to ith phase. An example of the coupling matrix is shown in Eq. 5. This matrix applies to any multi-phase IBC regardless of coupling strategy. The off-diagonal element of Eq. 5 represents the coupling coefficient of Hm,n shown in Eq. 2. It shall be noted that k (−1,1). Eq. 6 defines the variables in Eq. 1. Eq. 7 and 8 define variables in Eq. 2.

FIG. 5A represents a four-phase interleaved boost converter (model) where all the channels are coupled. Hence, first row of coupling matrix shown in Eq. 4 will [k1, 1k1,2, k1,3, k1,4] or [1, k, k, k] if all channels are having equal coupling coefficient(s) k. Similarly, for power converter of FIG. 5B (model), the first row of the coupling matrix will [k1, 1k1,2, k1,3, k1, 4] or as the first channel is not coupled with any other channels.

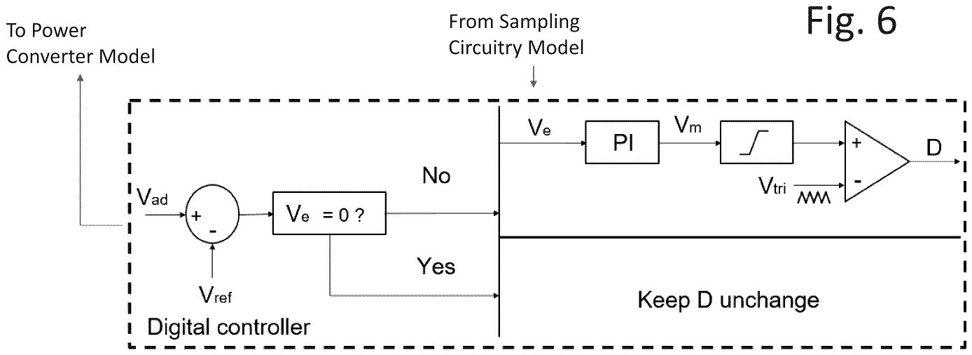

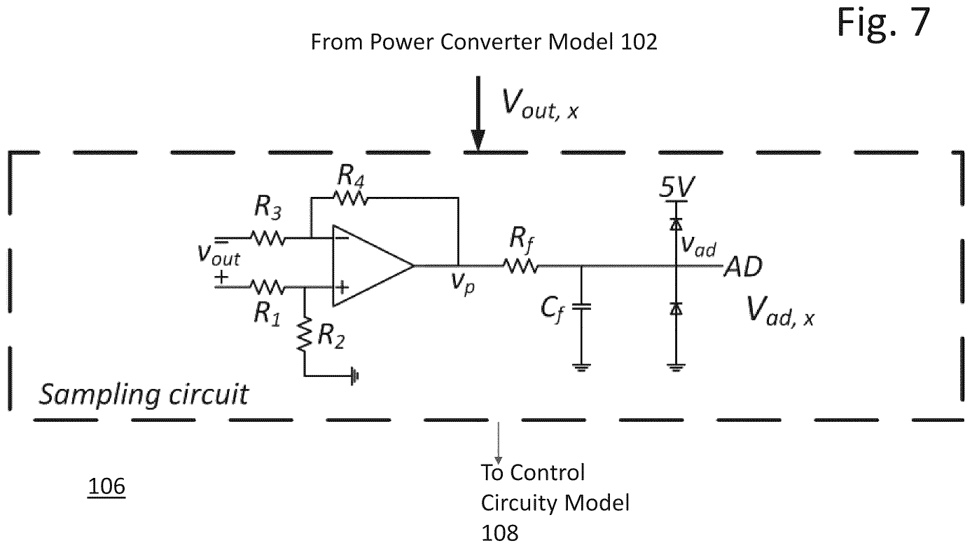

The digital twin 100 may also comprise a sampling circuitry model 106 and control circuitry model 108. An example of the control circuitry model 108 is shown in FIG. 6 and an example of the sampling circuitry model 106 is shown in FIG. 7. There may also be similar sampling circuitry model 106 for the current (per current sensor). For example, if there are two current sensors, then there may be two sampling circuitry models 106.

The control circuitry model 108 may also be determined using the RK state space method. The control circuitry model 108 may include a closed loop proportion integral (PI) controller. The PI controller may receive an adjusted input. The adjusted input may be adjusted by the sampling circuitry model 106.

The sampling circuitry model 106 receives a predicted sensed value and “samples” the same. In some aspects, where the predicted sensed value is an output voltage Vₒᵤₜ. The adjusted adc value of Vₒᵤₜ is referred to as V_{ad}. It shall be noted resolution or step size (h) defines the smallest voltage or current change possible for the ADC output signal in on time scale. Vₒᵤₜ to V_{ad} is based on sampling time h. An error signal is determined from the difference of the adjusted input (e.g., V_{ad}) and the reference value (e.g., V_{ref}). The error signal is referred to as Ve. The PI controller outputs a modulated value of the adjusted input such as Vₘ.

The PI controller has coefficients Kₚ and Kᵢ. Kₚ and Kᵢ are a function of the power converter. The V_{ref} may be the target output voltage. The target output voltage may be fixed. In other aspects, the target output voltage may be varied such as based on an external command from an external device (such as external device 25A or 25B). In FIG. 6, it is noted that D (the duty cycle is unchanged “Keep D unchange”, this is where the target output voltage is fixed. However, where the target output voltage is varied the duty cycle D may change as well as a function of the variance on the target output voltage.

This Vₘ signal is compared with Vₜᵣᵢ generated by DSP to achieve duty cycle D. It shall be noted that Vₜᵣᵢ is a triangular wave with values of 0-1 based on converter switching frequency. A subsequent modulation signal for the next prediction is a function of the adjusted input, coefficients Kp and Ki and the error. For example, Vm, x+1 may be determined from the following equation.

Vm,x+1=Vm,x+K_{P}(Ve,x+1−Ve,x)+KᵢhVe,x+1) (9)

The fixed triangular carrier signal has the same frequency as the switching frequency. If V_{m,x+1} is greater than to equal to V_{tri, x+1}, the switch is ON, otherwise, the switch is OFF (modeled as 1 or 0, where 1 is ON and 0 is OFF). Since each leg of the power converter has two switches complementary controlled, once the state of the first switch is represented the state of the second switch of the complementary controlled pair is also represented as the opposite. The states of each leg in the power converter may be represented in the same manner.

FIG. 7 illustrates an example of the sampling circuitry model 106 for sampling the output voltage Vₒᵤₜ.

The sampling circuitry model 106 is to synchronize the predicted data from the digital twin 100 with the sensed data. In an aspect of the disclosure, the sampling circuitry model 106 is based as a low pass amplifier-based RC network. The values for the resistance and the capacitor may be determined (estimated) using the RK 4^{th} order method. The input to the sampling circuitry model 106 is the predicted value from the power converter model 102 (for each prediction).

The digital twin 100 may also comprise a self-evolving monitoring function(s) 110. In an aspect of the disclosure, the self-evolving monitoring function 110 may include one or more multi-object determination functions. For example, one of the multi-object determination functions may be a particle swarm optimization (PSO) method. In other aspects, the multi-object determination function may include a genetic algorithm (GA). In other aspects, both the PSO and the GA may be used either sequentially or simultaneously. For example, multiple DSPs 10 may be executing the PSO and GA collectively or independently.

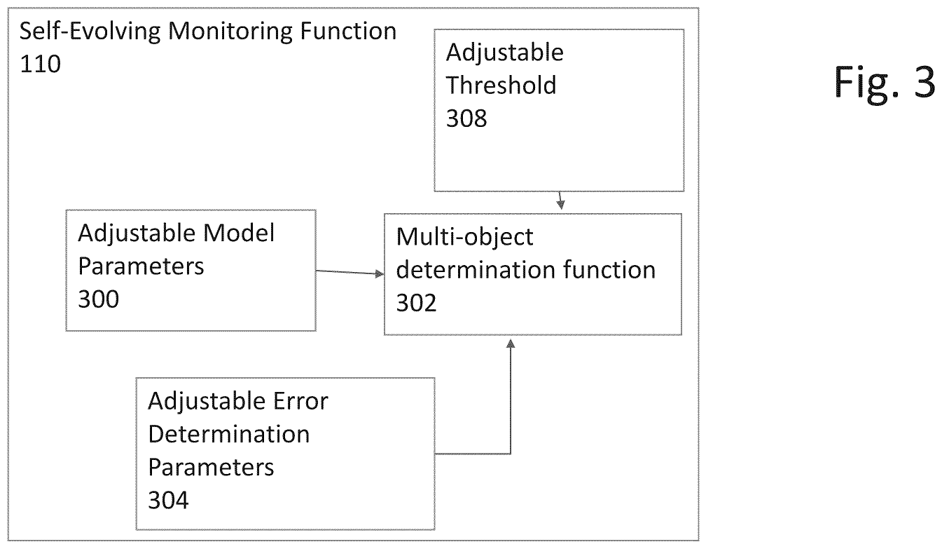

FIG. 3 illustrates a block diagram of the self-evolving monitoring function. Self-evolving means that the parameters may be initially set based on initial conditions in the power converter but may be adjusted as these conditions change or as needed based on predictions.

In an aspect of the disclosure, the self-evolving monitoring function 110 may comprise an adjustable threshold 308. This adjustable threshold is an allowable error threshold which is used to compare with a total difference Loss_{T}. The total difference is the amount (sum) of all of the differences between the predicted values and the actual measured values. This adjusted threshold effects the number of iterations to obtain a convergence.

In an aspect of the disclosure, the self-evolving monitoring function 110 may comprise one or more adjustable model parameters 300. The one or more adjustable model parameters 300 may be specific for the multi-determination function 302 such as the PSO and/or the GA.

For example, the one or more adjustable model parameters 300 may comprise one or more of the following: an adjustable learning rate λ, an adjustable global best rate γ₁, and adjustable personal best weight 72. The learning rate, adjustable global and personal best weights impact the selection of subsequent “particles” (sets of values for a swarm) to be selected for used in the prediction of sensed values, e.g., a velocity vector V.

The one or more adjustable model parameters 300 may also include weights for determining the total different Loss_{T}. For example, for each sensed value (and predicted value), a weight may be multiplied to the difference before adding together.

In an aspect of the disclosure, the self-evolving monitoring function 110 may account for different measurement errors. The different measurement errors may include, but are not limited to ADC conversion error, DC offset error, analog signal reconstruction and signal synchronization error. The measurement errors may be condition sensitive. The self-evolving monitoring function 110 may also comprise adjustable error determination parameters is as Q, which is a quantization error (parameter), B which is a parameter related to DC offset error and S, which is a parameter related to synchronization error. The maximum values for each parameter may be determined based on initial conditions and updated based on current operating conditions and measurements.

The parameters (adjustable model parameters 300, adjustable error determination parameters 304 and adjustable threshold 308) may be stored in memory 7 (onboard if the prediction is onboard or remote if the prediction is external).

In some aspects of the disclosure, the Sₘₐₓ, Bₘₐₓ and Qₘₐₓ may be determined for a plurality of known operating conditions and stored as a look up table in advance.

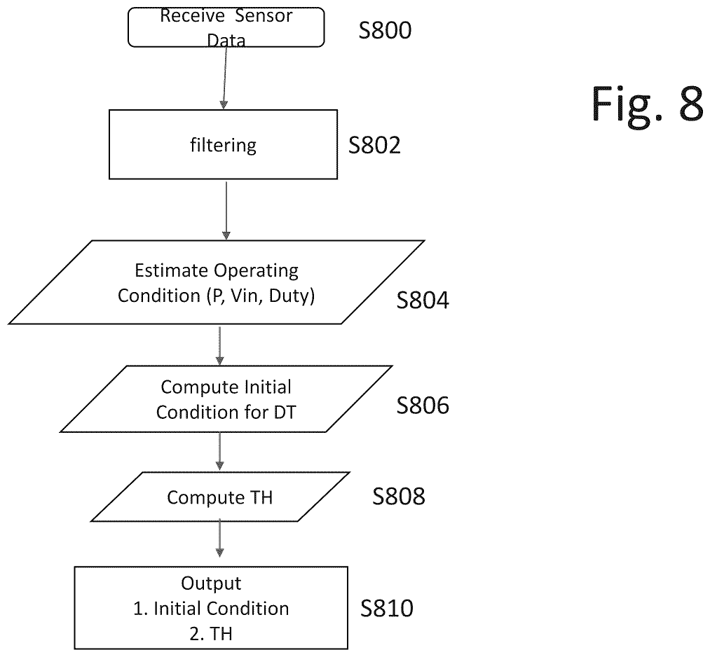

FIG. 8 illustrates a method for predicting the initial operating conditions of the power converter and initial value for the adjustable threshold 308 in accordance with aspects of the disclosure.

For purposes of the description of FIG. 8, the sensors 9 comprise a voltage sensor for sensing the output voltage Vₒᵤₜ and sensors for sensing leg current. I_{L1} through I_{LN}. At S800, the DSP 10 receives the sensor data from the sensors 9 (via the ADC 13). The sensor data is received for a preset period of time prior to the estimation (at S804). This is because in order to estimate the duty cycle, a pattern needs to be formed for at least one cycle. Since the sampling rate has multiple points in a cycle, sensed data needs to be received for at least one cycle. At S802, the received sensor data is filtered. In some aspects of the disclosure, Savitzky Golay filtering may be used by the DSP 10. This is a digital filter used to smooth the data and to achieve partial immunity from small signal noise.

At S804, the DSP 10 estimates the initial operating conditions from the sensed data. These initial operating conditions may include power P (input power), input voltage Vᵢₙ and the duty cycle D. In an aspect of the disclosure, an input voltage sensor may not be used. D may be estimated based on the sampled pattern data. Vᵢₙ may be estimated from the estimated D and the sensed output voltage. The input power P may also be estimated from the estimated Vin input voltage and a sum of the sensed leg current I_{L1} through I_{LN}. The operating conditions are important to consider when determining the threshold 308 because the relative error may be substantially different for different operating conditions. For example, for high power applications such as 1000V, the impact of a 1V error in the prediction may not be significant but when the application only has 10V a 1V error may be significant.

At S806, the DSP 10 estimates the initial conditions for the digital twin 100 (from the models). For example, the DSP 10 may estimate the leg current. The leg condition may be estimates from the following equations:

$${i}_{L 1} = \frac{{P}_{in}}{{4}^{*} Vin} - \frac{Δ {i}_{L}}{2} \qquad ( 10 )$$

$${i}_{L 2} = \frac{{P}_{in}}{{4}^{*} {V}_{in}} - \frac{Δ {i}_{L}}{2} + \frac{{V}_{in} - {V}_{O}}{L} * \frac{0.5 - D}{{f}_{sw}} \qquad ( 11 )$$

where L is the inductor normal value. This may be provided by the manufacturer of the power converter. D is the estimated duty cycle, f_{sw} is the switching frequency, “ΔiL” is the difference in the minimum and maximum current across the inductor determined from the duty cycle D, input voltage Vin and the switching frequency f sw. The switching frequency may be estimated by the pattern of predicted values or the pattern of the sensed values. Pin, Vin, Vo are estimated from the nominal values of the components. In other aspects, sensed values may be used.

At S808, the DSP 10 determines the initial value for the threshold 308. The threshold 208 may be determined based on an equation. For example, the threshold 308 may be determine using the following:

TH=0.02*(Σαₐ(ILa_{,max})2+β(V_{o,max})² (12)

“αₐ” and β may be default values of the summation weights as described above and stored in memory 7. There may be a different default value depending on the power converter type and Related Variant. The output voltage maximum and leg current maximum may be determined in S804.

The initial values for the error determination parameters may also be determined from the initial operation conditions (actual conditions).

Analog signal reconstruction of the non-bandlimited signal, i.e., triangular signal, saw tooth waveform may impact the prediction and thus Loss_{T}. For example, the inductor channel current can be seen as a triangular waveform or a combination triangular waveform based on switching states and the number of phases. The bandwidth of a triangular signal approaches infinite theoretically. Therefore, the selection of sampling frequency is needed to closely approximate the signal.

The minimum sampling frequency may be based on the switching frequency of the switches, the duty cycle and number of states of operation (plateaus) It is preferred that the sampling rate is more than the minimum sampling frequency. The minimum bandwidth BWmin can be given as

$$BW min = \frac{2}{{min}_{j = 1 , 2 , … , {S}_{s}} ( T ( {s}_{j} ) )} \qquad ( 13 )$$

where, S is number of switching states, T(sj) is time per switching state. For instance, for a simple buck converter with a duty period D and switching frequency fsw, the BWmin as 2*fsw/D and 2*fsw/(1−D) for D<0.5 and D≥0.5 respectively. Hence, the minimum step size hmin can be given by (BWmin)−1.

However, irrespective of how high sampling frequency is selected; there may be an error due to non-simultaneous sampling error based on the number of sample and hold (S/H) circuits in the current sensor (sensor 9) is present. The maximum error due to the step size resolution of the current sensor can be determined by:

$${R}_{max} = \frac{( {I}_{max} - {I}_{min} ) * {T}_{sampling}}{2 * {T}_{SW}} \qquad ( 14 )$$

where, Imax and Imin are maximum and minimum values of inductor current as determined above. Tsampling and Tsw are switching and sampling time used (which is based on the known sampling rate).

In an aspect of the disclosure, the DSP 10 adjusts the received sensed data based on Rₘₐₓ.

The ADC conversion noise is prone to multiple errors due to the metastable state of analog to digital converter at high frequency. Such errors can heavily impact the accuracy and precision of condition monitoring.

Quantization error consists of two components: amplitude and time quantization. Time quantization implies the ADC 13 is unable to adjust its sampling frequency and interval during an active sampling window, thus missing out on crucial information, whereas amplitude quantization implies an error in the accuracy of the ADC 13 due to resolution. The sampling circuit significantly impacts quantization error due to amplitude. The quantization error e may be modeled as a random variable and uniformly distributed in amplitude between ±Δ/2. The quantization step size Δ may be defines as:

$$Δ = \frac{2 D}{2 K} = {2}^{- ( K - 1 )} D \qquad ( 15 )$$

D is a dynamic range signal (peak-to-peak) and K is the bit resolution of the ADC.

Moreover, when interfacing with the sensor, the maximum quantization and resolution errors add up to give a final error Qmax. Qmax may be determined from the following equation:

$${Q}_{max} = {R}_{max} \pm \frac{Δ}{2} \qquad ( 16 )$$

In an aspect of the disclosure, as noted above, the ADC 13 may be a 16-bit, counter-driven ADC with a +Vref of 3.0V and a −Vref0.0V. Therefore, the theoretical amplitude quantization error allowed to any signal given as input to the ADC 13 is between ±45.78 μV.

In an aspect of the disclosure, the estimated Q (based on the operating conditions) is used to offset or compensate for the error (for every switching cycle). All errors near the peaks are effectively neglected. For example, in an aspect of the disclosure, the amplitude equalization error gets added on top of the Rₘₐₓ for compensation.

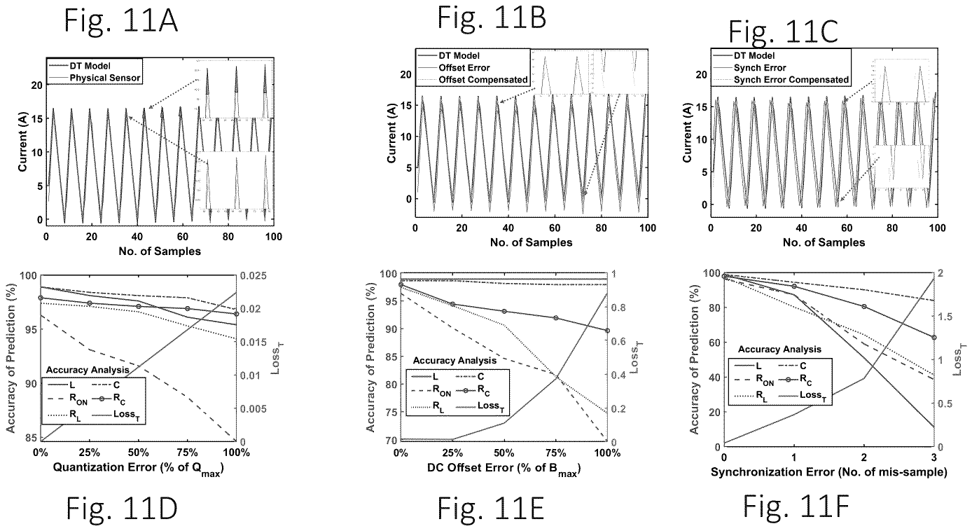

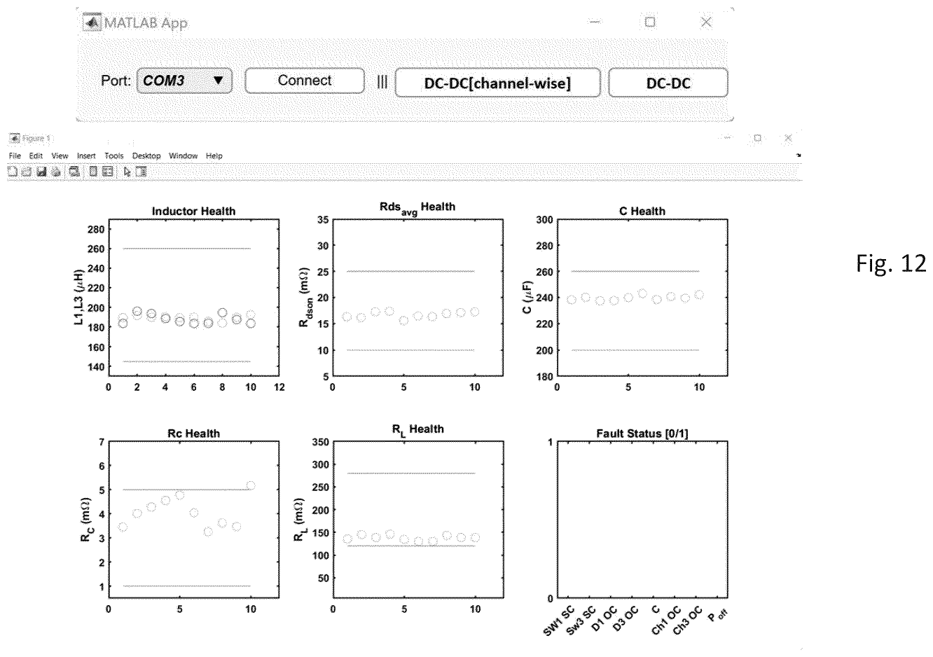

FIG. 11A illustrates an example of (max. Inset in FIG. 11A are two sets of peaks. Sampled sensor data cannot capture inductor peak values due to Qmax. This leads to the continuous error between the prediction from the digital twin 100 and sampled sensor data from the sensors 9, as signified in FIG. 11A.

FIG. 11D shows an example of the impact of varying amplitude quantization from 0 to Qmax. Inset in FIG. 11D shows a legend identifying which values of a power converter are being predicted for a four legged converter. As can be seen, the accuracy of estimation of Ron and Rz is significantly impacted by quantization error. However, this does not impact the estimation of L, C. This is because quantization error mainly leads to an error in the peak value of the inductor current but has less impact on the slope of the inductor current or RC time constant for voltage waveform. This leads to a stable and robust estimation of L, C.

In accordance with aspects of the disclosure, an evaluation of the accuracy for the different predictions may help the user to identify the type of error they are encountering in the prediction.

The sensor also generates offset and gain errors that are in addition to the amplitude quantization error. An offset error is a small pre-existing output from the transducer due to uncertainties from the electronics and magnetic core retentively. This offset should be as low as possible since this offset contributes to additional errors while measuring DC current/DC voltage. Similarly, the ideal gain of the sensor 9 is expected to be linear, but due to electronic uncertainty, the sensor 9 does not always satisfy linearity (gain error).

A similar error can be observed from the ADC 13. It is noted that each ADC has a conversion range determined from V_{ADCref}. For example, V_{ADCref} may be between 0V and 3V. Any analog input to the ADC 13 beyond 3V will be clipped off to 3V. The offset error due to ADC 13 is defined as the deviation between the first actual transition and the first ideal transition. The first transition is when the digital output of ADC 13 changes from 0 to 1. The offset error can be calculated by finding the difference between V_{ADCin} and 0.5Δ, where V_{ADCin} is the actual input voltage of the first transition and Δ is the quantization step of the ADC 13.

Similarly, the gain error is defined as the deviation between the last actual transition and the last ideal transition. The last transition is when the digital output of ADC changes from 2^{R}−2 to 2^{R}−1, where R denotes the resolution of the ADC. To find the gain error, first calculate the difference between V_{ADCin} and +V_{ADCref}−0.5Δ, where V_{ADCin} is the actual input voltage of the last transition to the ADC and A is the quantization step of the ADC 14. The compound of all such errors is defined as Bmax and may be determined based on the difference in the minimum values from the sensor 9 and from the digital twin 100. This difference is determined initially to set the Bmax using the nominal circuit values and initial operating conditions (and sequentially updated based on predicted parameters)

Bₘₐₓ=|min(I_{L┌sensor┐})−min(I_{L┐DT┌})| (17)

This gives the condition monitoring the ability to compensate for DC offset error. The difference may be added/subtracted as needed to either the predicted value or the sensor data.

FIG. 11B illustrates an example of offset error. Inset are peaks and valleys to highlight the shift and compensation. FIG. 11E illustrates the different effect of this offset error in the prediction accuracy of the various values. As can be seen, DC offset error Bmax can mainly impact the estimation accuracy of parameters RON,RL, and RC. As can be seen in FIGS. 11D v. 11E, the impact of the DC offset error may be greater than the quantization error on the prediction.

Synchronization between the sampled waveform and its analog counterpart is important. If synchronization lapses by a single sample (sample point), it can greatly harm the prediction. The source for such synchronization error can be an embedded circuit, sensing delay or communication delay. Time synchronization can also develop with the number of iterations on the sampling circuit. For instance, if 480.1 kHz sampling is done instead of 480 kHz sampling for a 60 kHz signal; then a synchronization error will be observed with 588th iteration of the sensor.

FIG. 11C shows an example the prediction out of synchronization. Once again, inset are two areas highlights the synchronization error in the peaks and valleys. As can be seen, the two current measures/predictions are not aligned, but offset in time (number of sample). DT refers to the model. Here the compensation shifts either the prediction or the actual sensed data (left/right).

FIG. 11F shows the impact by the synchronization on the prediction of the different values. The error increases (the figure shows out of synch up to three samples). As can be seen once again, the error may differentially impact the prediction of values differently. For example, a miss synchronization by 1 or 2 samples can significantly reduce prediction accuracy for parameter L,R_{ON} and R_{L}. This is mostly as synchronization error mainly varies computation of rising and falling slope computation of the digital twin 100, which may impact the prediction of inductance the greatest. However, the estimation accuracy does not significantly fall for the estimation of C and RC. This impact of synchronization error can be compensated by computing and compensating delay of sensing, communication, and time quantization and adding a pre-processing synchronization to one set of data.

Smax may be determined as follows:

Sₘₐₓ=duty*T_{sw}/Tₛ. (18)

Smax may be calculated at the initial operating condition(s) and subsequently updated.

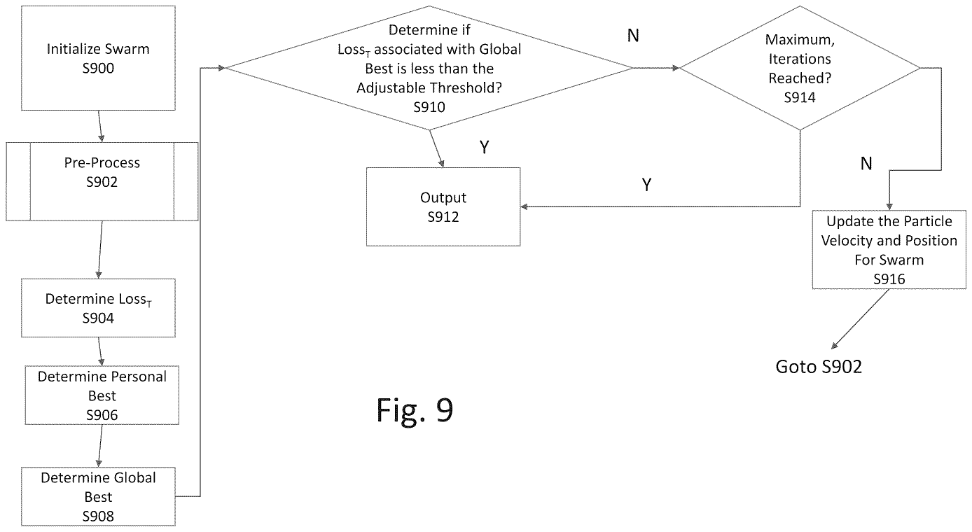

FIG. 9 illustrates a method of the self-evolving monitoring function 110 in accordance with aspects of the disclosure. The method may be executed by the DSP 10. The features illustrated in FIG. 9 are executed each monitoring cycle. The monitoring cycle may be minutes, hours, etc. such that the DSP 10 periodically outputs the result of the predictions. The specific timing of the monitoring cycle may be application specific or may be a parameter set by a manufacture of the power converter. At S900, the DSP 10 initializes a swarm. The swarm contains multiple sets of elements. The number of sets may be user specified. The number of elements in each set is power converter specific and based on the component in the specific power converter and corresponding model 102. For example, for the model of the power converter depicted in FIG. 5C (102C), the set may include the capacitance “C”, inductance L (for each leg), resistance of the capacitor R_{C}, the lumped device on-resistance Ron (for each leg), inductor resistance R_{L} (for each leg). However, for other topologies and power converter, the number and elements may be different.

In an aspect of the disclosure, the values for each element of the set may be initially randomly determined. For example, if the swarm size is 10, the DSP 10 initializes 10 sets of values, where each set is randomly determined.

In other aspects of the disclosure, some of the initial values within a set may be randomly determined, while others may be calculated. For example, the inductance may be calculated. Given a high precision sampling circuit, L can be calculated at very high accuracy using the following equation

$$L = \frac{{v}_{L}}{\frac{{di}_{L}}{dt}} \qquad ( 19 )$$

where vL and iL are the voltage across the inductor and current through the inductor; and di/dt is the slope of channel current.

In other aspects of the disclosure, the capacitor resistance R_{c}, and the inductor resistance (R_{L}) (per leg), may be estimated using linear curve fitting of a decoupling approach. Advantageously, by using this calculation and estimation (as opposed to fully random), a DSP 10 with a lower computational processing may be used and the memory size required may also be reduced. Additionally, this may speed up the convergence of the predictions with the actual measurements.

While a value for each element in the set (and in each set) may be randomly set, the random value may be determined between a preset minimum and a preset maximum for each element, respectively. The preset minimums and maximums may be component specific and based on the nominal values of each component. For example, the preset minimum and preset maximums may be based on the specification sheet for the respective components (if available).

Once the swarm in fully initialized with values for each element in the set (and for each set), the swarm is supplied to the power converter circuit model 102 (and used in the state equations) to predict one or more values corresponding to the actual sensed values such as voltage and/or current. Once again, for example, referring to the model of the power converter depicted in FIG. 5C (102C), there are five actual sensed values (four leg currents) and one output voltage.

The sensed values are predicted using the values in the swarm, e.g., if the swarm size is 10, then the DSP 10 predicts 10 sets of values (currents and/or voltages), one for each set within the swarm. The DSP 10 also receives the actual detected values from the sensors 9 (via the ADC 13). Each measurement has a plurality of measurement points Np. Therefore, for each comparison, there are also Np prediction by the DSP 10.

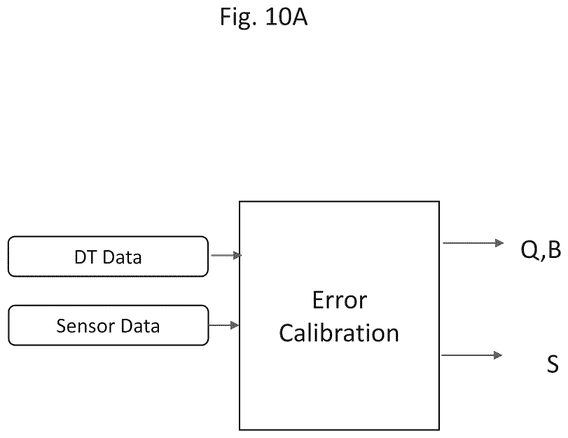

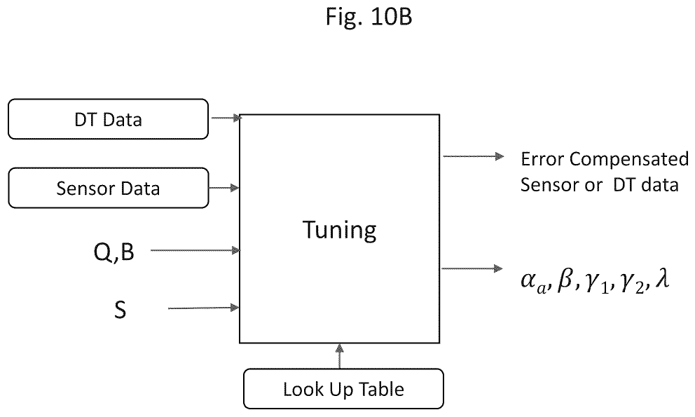

At S902, the DSP 10 executes a pre-processing process. The pre-processing process is both to correct for one or more of the above defined errors including quantization error, DC offset error and synchronization error and to update the adjustable threshold 308 and model parameters 300 and the error determination parameters 304. FIGS. 10A and 10B illustrate an example of the pre-processing process. This process is repeated for each iteration to adjust based on the current conditions and measurement. As shown in FIG. 10A, error determination parameters 304 are adjusted based on the predictions from the digital twin 100 (as described above) and from the received actual sensor data from the sensors 9 (via the ADC 13). The Q, B and S are calculated in a similar manner as described above such as using EQs. 16-18.

The calculated Q, B and S (real-time) may be compared with the initial values determined above (Qₘₐₓ, Bₘₐₓ and Sₘₐₓ) to generate three error signals. In other aspects, the Qₘₐₓ, Bₘₐₓ and Sₘₐₓ may be retrieved from a look up table such as shown in FIG. 10B.

Each error signal (e1, e2, e3) may be obtained by dividing the respective current values with the maximum value(s) for each. For example, e1 may be determined by e1=Q/Qₘₐₓ. Similarly, e2 may be determined by B/Bₘₐₓ and e3 may be determined by S/Sₘₐₓ.

These error signals e1, e2, and e3 may be used to update the threshold 308 and model parameters 300. For example, in an aspect of the disclosure, the error signals e1, e2, and e3 may be used to define a tuning parameter T. In an aspect of the disclosure, the tuning parameter may be defined as 1-maximum (e1, e2 and e3).

Each of the model parameters 300 may be based on this tuning parameter. For example, the weight for current (sensor and predicted) “a” may be equal to a preset number Z multiplied by T. In some aspects, this preset number Z may be 200. The value for a (for a leg) may also be based on the maximum current sensed (for the leg) where the maximum current sensed is in the denominator. The weights are inversely proportional to the sensor integrity error.

Similarly, the weight for voltage (sensor and predicted) “B” may also equal to another preset number Y multiplied by T. In some aspects of the disclosure, the preset number Y may be 100. However, other values for Y and Z may be used. However, if T is negative, than the error is too high, and in an aspect of the disclosure, the prediction and measurements may be ignored (the weights may be floored to zero for the specific sensor/data). These weights account for different sensor errors. If a sensor is bad, the weights may enable the DSP 10 to reduce the impact from the bad sensor (e.g., the error increases in time or stops worked altogether).

The learning rate λ and the global best and personal best weights γ₁, γ₂ may also be based on the tuning parameter T. For example, the learning rate A may be a multiple of T (both integer and non-integer). For example, learning rate λ may be a percentage of T such as 60%. The global best weight γ₁ may also be a multiple of T such as 5 or 10. The personal best weight γ₂ may be a multiple of 1−T. For example, the personal best weight may be 3 (1−T). In some aspects of the disclosure, when there are multiple legs, the learning rate λ may be defined as the minimum rate determined for each leg. In some aspects of the disclosure, when there are multiple legs, the global best and personal best weights γ₁, γ₂ may be defined as the maximum determined for each leg such that the same is used for each leg.

In some aspects, the determination of learning rate λ and the global best and personal best weights γ₁, γ₂ may be different if T is negative. For example, when Tis negative, T may not be used in the calculation of the learning rate λ and the global best and personal best weights γ₁, γ₂. In some aspects, when T is negative, the learning rate λ may be assigned a set value such as 0.6. Global best weight γ₁ may be assigned a set value such as 5 and the personal best weight γ₂ may be assigned a value such as 3.

Once α and β are determined, the threshold 308 may be determined based on EQ. 12 as described above.

As shown in FIG. 10B, the DSP 10 also compensates either the data from the sensors or the prediction of the corresponding values based on the calculated error parameters B, Q, S (real-time) such as by shifting left or right by samples or up or down by magnitude.

At S904, the DSP 10 determines the quality of the prediction for each set in the swarm. The quality of the prediction may be based on a Loss_{T} which is based on the total error between the prediction of each sensed value and the actual detection. In an aspect of the disclosure, the error may be evaluated using a lead square error (LSE) approach. For example, when the measurement is the leg current and the output voltage the error may be defined as

$$\{ \begin{matrix}{LSE}_{{I}_{L}} ( x ) = \frac{1}{{N}_{p}} {Σ}_{a = 1}^{N} {{Σ}_{b = 1}^{{N}_{p}} ( {i}_{La ( DT )}^{b} - {i}_{La ( sensor )}^{b} )}^{2} \\ {LSE}_{{V}_{o}} ( x ) = \frac{1}{{N}_{p}} {{Σ}_{b = 1}^{{N}_{p}} ( {V}_{o ( DT )}^{b} - {V}_{o ( sensor )}^{b} )}^{2}\end{matrix} \qquad ( 20 )$$

where, iL(sensor) and Vo(sensor) are data collected from the sensors 9. Similarly, iL DT) and Vo(DT) are predictions. Also, N is the number of legs, and Np is the number of points.

Loss_{T} than may be determines by the following equation:

LossT=αaLSE_{ILa}+βLSE_{Vo} (21)

However, other approaches may be used.

Thus, for a swarm size of 10, the DSP 10 determines 10 Loss_{T}. In an aspect of the disclosure, each determined Loss_{T} may be stored in memory 7 and associated with the set. In some aspects of the disclosure, the determined Loss_{T} may be sorted in increasing order (or decreasing order) for the swarm. α and β are the weights determined above and are adjustable.

At S906 and S908, the DSP 10 determines the personal best and global best. The personal best is the set of values with correspond to the smallest Lossy for the specific swarm. The personal best is stored for each iteration. The global best is the set of values with correspond to the smaller Loss_{T} across all swarms (lowest of the all personal bests). For a first iteration, the global best and the personal best are the same.

At S910, the DSP 10 determines whether the Loss_{T} associated with the best swarm is less than or equal to the above determined adjustable threshold 308 (error threshold). In other words, is the prediction good enough? In a case where the DSP 10 determines that the LossT is less than the adjustable threshold 308, the values in the set associated therewith are output at S912. These values may be included an in report as the health of the power converter.

On the other hand, in a case where the Loss_{T} associated with the best swarm is greater than the above determined adjustable threshold 308 (error threshold), the DSP 10 determines whether a maximum number of iterations is reached. The maximum number of iterations may be based on the DSP power, the type of power converter, etc. When the maximum number of iterations is reached, even though Loss_{T} is still high (greater than the threshold), the DSP 10 still outputs the values in the set (associated with the personal best) as the health of the power converter. In an aspect of the disclosure, the DSP 10 may also output an indicator indicating that the maximum number of iterations is reached. Also in an aspect of the disclosure, the DSP 10 may also output the calculated Loss_{T} along with the values in the set (associated with the personal best). In some aspect, the calculated Loss_{T} may be the indicator.

In other aspects, even when the predicted values converge with the actual values, the DSP 10 may also output the calculated Loss_{T}.

In a case where the maximum number of iterations is not reach (NO at S914), the DSP 10 populates the values in each set (and for the multiple sets) in the swarm at S916. This is based on updating a velocity (amount of change in value) and the position. The values for used in the subsequent iteration for the model (prediction) may be determined as follows:

$$\{ \begin{matrix}\begin{matrix}{V}_{m , n} = {λ}_{m - 1} {V}_{m - 1 , n} + 2 {γ}_{1 m - 1 , n} ( {G}_{best} - {P}_{m - 1 , n} ) + \\ 2 {γ}_{2 m - 1 , n} ( {P}_{best} - {P}_{m - 1 , n} )\end{matrix} \\ {P}_{Rm , n} = {P}_{Rm - 1 , n} + {V}_{m , n}\end{matrix} \qquad ( 22 )$$

where n is the number of particles (number of sets of values in the swarm) and m is the number of iterations.

In an aspect of the disclosure, once the DSP identifies the best, the DSP 10 stores the same with a flag such that it may be subsequently transmitted. For example, the FPGA 15 may retrieve the best from the memory 7 and cause the set to be transmitted to the external device 25A as the health of the power converter. For example, the FPGA 15 may use the communication interface 11 to transmit the health of the power converter to the external device 25A. In an aspect of the disclosure, the set of values may be transmitted as a single packet. In some aspects, as described above, an indicator whether the maximum number of iterations may be include in this single packet. The packet may include an identifier of each type of value (component or parasitic) such that each “channel” of information may be identified. In an aspect of the disclosure, the parameter used by the DSP for the prediction may also be included in the packet.

The size of the packet may depend on the type of power converter and the particular variant. For example, as the number of legs increases, the size of the packet may increase.

In an aspect of the disclosure, the external device 25A may display a dashboard showing the health of the power converter based on the received information from the FPGA 15. The dashboard may have a separate chart or graph for each channel. In an aspect of the disclosure, the dashboard may be created from an open source program. In some aspects, the dashboard may be created in a MATLAB GUI.

FIG. 12 illustrates an example of a dashboard displayed on the display 27 of the external device 25A or 25B. As depicted, there are six channels of data. However, the dashboard may be customized by a user to display a different number of channels or a different time window. Each channel shows a change in the respective value over time. This enables the viewer to identify the power converter degradation (error in the power converter).

In an aspect of the disclosure, other sensors such as temperature sensors may be included in the system. These other sensors may be able to confirm a power converter degradation or debunk the same to distinguish between a temperature-based component fluctuations or an actual component degradation.

In accordance with a first aspect, a digital twin may be used to determine a health of a power converter. The digital twin may comprise a plurality of state equations representing circuit components of the power converter and at least one associated value for each component. Each state equation is capable of representing the circuit components for a defined power converter topology and related variants, and a self-evolving monitoring function. The self-evolving monitoring function has adjustable model parameters, an adjustable threshold and adjustable determination parameters.

In accordance with a second aspect, the digital twin according to the first aspect, where the adjustable model parameters include summation weights used to add a digital twin voltage and a digital twin current. The summation weights may be individually adjustable based on error detection with respect to physical sensors for the power converter.

In accordance with a third aspect, the digital twin according to the first aspect or the second aspect, the adjustable determination parameters may be individually adjustable based on error detection.

In accordance with fourth aspect, the digital twin according to the third aspect, wherein the adjustable determination parameters include a learning rate and weights for local and global best.

In accordance with a fifth aspect, the digital twin according to any one of the first aspect through fourth aspect, wherein the adjustable threshold is set based on operating conditions for the power converter, such as, a maximum output voltage or maximum inductor current.

In accordance with a sixth aspect, the digital twin according any one of the first aspect through the fifth aspect, wherein the adjustable threshold is initialized during a calibration period.

In accordance with a seventh aspect, a method of using the digital twin according to any one of the first aspect through the sixth aspect to determine the health of the power converter, the method comprising receiving a sensed value from one or more sensors, respectively. The one or more sensors may be a voltage sensor and/or a current sensor for sensing voltage and/or current within the power converter, respectively. The method further comprises defining at least one set of values for the components of the power converter in the digital twin using the self-evolving monitoring function, determining, using the self-evolving monitoring function, digital twin voltage and/or current corresponding to the sensed voltage and/or current respectively based on each defined set of values, comparing, using the self-evolving monitoring function, each determined digital twin voltage and/or current, with values obtained from the corresponding sensors, determining, using the self-evolving monitoring function, a difference between each determined digital twin voltage and/or current and values obtained from the corresponding sensors using adjustable model parameters of the self-evolving monitoring function and outputting one of the at least one set of values as the health of the power converter when the determined difference is less than an adjustable threshold of the self-evolving monitoring function. When the difference is greater than the adjustable threshold, the method repeats, the defining, the determining, the comparing, the determining and outputting. These features are repeated using new at least one set of values for the components of the power converter in the digital twin until a condition is met. The new at least one set of values are based on adjustable determination parameters of the self-evolving monitoring function.

In accordance with an eighth aspect, a method according to the seventh aspect, wherein a subset the values in each set are randomly determined.

In accordance with a ninth aspect, a method according to the eighth aspect, wherein certain values are calculated in each set of values.

In accordance with a tenth aspect, a method according to the seventh aspect, eighth aspect or ninth aspect, wherein the received sensed values from the one or more sensors are compensated based on error detection to determine the values obtained from the corresponding sensors or the determined digital twin current and/or voltage are compensated based on error detection.

In accordance with an eleventh aspect, a method according to any one of the seventh aspect through tenth aspect, wherein the error detection comprises determining at least quantization error, DC offset error and synchronization error.

In accordance with a twelfth aspect, a method according to any one of the seventh aspect through eleventh aspect, wherein the circuit components include switches and inductors and the at least one set of values includes Resistanceₒₙ, inductance and inductor resistance, and wherein the method comprises determining the Resistanceₒₙ and inductor resistance independently where the inductor resistance is predicted during inductor discharging and the Resistanceₒₙ is predicted during inductor charging.

In accordance with a thirteenth aspect, a method according to any one of the seventh aspect through twelfth aspect, wherein the plurality of state equations and the self-evolving monitoring function are stored in a memory and executable by a processor embedded with a housing of the power converter and the outputting comprises transmitting a packet to an external device.

In accordance with a fourteenth aspect, a method according to the thirteenth aspect, wherein the outputting further comprises causing a display on the external device to display the health of the power converter.

In accordance with a fifteenth aspect, a method according to the fourteenth aspect, wherein when the condition is met and the difference is still greater than the adjustable threshold, the packet includes one set of values with a smallest difference and the determined difference; otherwise, when the difference is smaller than the adjustable threshold the packet includes the one set of values without the determined difference.

In accordance with a sixteenth aspect, a method according to the fourteenth aspect or the fifteenth aspect, wherein the values for different component types in the one set of values are separately displayed on the display.

In accordance with a seventeenth aspect, a method according to the fourteenth aspect, the fifteenth aspect or the sixteenth aspect, wherein (b)-(g) are repeated for each new sensed value from the one or more sensors in (a).

In accordance with an eighteenth aspect, a method according to the seventeenth aspect, wherein the display shows a change of the values over time, respectively.

In accordance with a nineteenth aspect, a method according to the eighteenth aspect, further comprising determining a fault condition based on the change in the value over time and displaying indication based on the determination.

In accordance with a twentieth aspect, according to any aspect, the power converter may be a multi-phase boost converter.

In accordance with a twenty-first aspect, a health monitoring system for a power converter. The health monitoring system comprise a memory, a voltage sensor, a current sensor and a processor. The memory stores a digital twin comprising a plurality of state equations representing circuit components of a power converter and at least one associated value for each component. Each state equation may be capable of representing the circuit components for a defined power converter topology and related variants. The memory may further store a self-evolving monitoring function having adjustable model parameters, adjustable threshold and adjustable determination parameters. The adjustable model parameters may include weights for combining determined voltage and determined current, respectively. The adjustable determination parameters may be used to determine sets of values for the components for predicting the voltage and current, respectively. The voltage sensor is configured to detect a voltage of the power converter and the current sensor is configured to detect a current within the power converter. The processor is configured to receive the detected voltage from the voltage sensor and the detected current from the current sensor, define at least one set of values for the components of the power converter in the digital twin using the self-evolving monitoring function, determine, using the self-evolving monitoring function, digital twin voltage and current corresponding to the sensed voltage and current respectively, based on each defined set of values, compare, using the self-evolving monitoring function, each determined digital twin voltage and current, with values obtained from the corresponding sensors, determine, using the self-evolving monitoring function, a difference between each determined digital twin voltage and current and values obtained from the corresponding sensors using the adjustable model parameters of the self-evolving monitoring function and output one of the at least one set of values as the health of the power converter when the determined difference is less than the adjustable threshold of the self-evolving monitoring function. In an aspect of the disclosure, when the difference is greater than the adjustable threshold, the processor is configured to repeat the defining, determining, comparing, and determining using new at least one set of values for the component of the power converter in the digital twin until a condition is met. The new at least one set of values may be based on the adjustable determination parameters of the self-evolving monitoring function.

In accordance with as twenty-second aspect, the health monitoring system of the twenty-first aspect, wherein the memory is on-board memory co-located with the power converter and the system further comprises a communication interface configured to transmit the one of the at least one set of values as the health of the power converter or a set of values having a smallest difference when the condition is met.

In the discussion and claims herein, the term “about” indicates that the value listed may be somewhat altered, as long as the alteration does not result in nonconformance of the process or device. For example, for some elements the term “about” can refer to a variation of ±0.1%, for other elements, the term “about” can refer to a variation of ±1% or ±10%, or any point therein. For example, the term about when used for a measurement in mm, may include +/0.1, 0.2, 0.3, etc., where the difference between the stated number may be larger when the state number is larger. For example, about 1.5 may include 1.2-1.8, where about 20, may include 19.0-21.0.

As used herein, the term “substantially”, or “substantial”, is equally applicable when used in a negative connotation to refer to the complete or near complete lack of an action, characteristic, property, state, structure, item, or result. For example, a surface that is “substantially” flat would either completely flat, or so nearly flat that the effect would be the same as if it were completely flat. “Substantially” when referring to a shape or size may account for manufacturing where a perfect shapes, such as circular or sizes may be difficult to manufacture.

As used herein terms such as “a”, “an” and “the” are not intended to refer to only a singular entity, but include the general class of which a specific example may be used for illustration. As used herein, terms defined in the singular are intended to include those terms defined in the plural and vice versa.

References in the specification to “one aspect”, “certain aspects”, “some aspects” or “an aspect”, indicate that the aspect(s) described may include a particular feature or characteristic, but every aspect may not necessarily include the particular feature, structure, or characteristic. Moreover, such phrases are not necessarily referring to the same aspect. Further, when a particular feature, structure, or characteristic is described in connection with an aspect, it is submitted that it is within the knowledge of one skilled in the art to affect such feature, structure, or characteristic in connection with other aspects whether or not explicitly described. For purposes of the description hereinafter, the terms “upper”, “lower”, “right”, “left”, “vertical”, “horizontal”, “top”, “bottom”, and derivatives thereof shall relate to a device relative to a floor and/or as it is oriented in the figures.

Reference herein to any numerical range expressly includes each numerical value (including fractional numbers and whole numbers) encompassed by that range. To illustrate, reference herein to a range of “at least 50” or “at least about 50” includes whole numbers of 50, 51, 52, 53, 54, 55, 56, 57, 58, 59, 60, etc., and fractional numbers 50.1, 50.2 50.3, 50.4, 50.5, 50.6, 50.7, 50.8, 50.9, etc. In a further illustration, reference herein to a range of “less than 50” or “less than about 50” includes whole numbers 49, 48, 47, 46, 45, 44, 43, 42, 41, 40, etc., and fractional numbers 49.9, 49.8, 49.7, 49.6, 49.5, 49.4, 49.3, 49.2, 49.1, 49.0, etc.

As used herein, the term “processor” may include a single core processor, a multi-core processor, multiple processors located in a single device, or multiple processors in wired or wireless communication with each other and distributed over a network of devices, the Internet, or the cloud. Accordingly, as used herein, functions, features or instructions performed or configured to be performed by a “processor”, may include the performance of the functions, features or instructions by a single core processor, may include performance of the functions, features or instructions collectively or collaboratively by multiple cores of a multi-core processor, or may include performance of the functions, features or instructions collectively or collaboratively by multiple processors, where each processor or core is not required to perform every function, feature or instruction individually. For example, a single FPGA may be used or multiple FPGAs may be used to achieve the functions, features or instructions described herein. For example, multiple processors may allow load balancing. In a further example, a server (also known as remote, or cloud) processor may accomplish some or all functionality on behalf of a client processor.

As used herein, the term “processor” or the term “controller” may be replaced with the term “circuit” such as an ASIC. The term “processor” may refer to, be part of, or include processor hardware (shared, dedicated, or group) that executes code and memory hardware (shared, dedicated, or group) that stores code executed by the processor.

Further, in some aspect of the disclosure, a non-transitory computer-readable storage medium comprising electronically readable control information stored thereon, configured in such that when the storage medium is used in a processor, aspects of the functionality described herein is carried out.

Even further, any of the aforementioned methods may be embodied in the form of a program. The program may be stored on a non-transitory computer readable medium and is adapted to perform any one of the aforementioned methods when run on a computer device (a device including a processor). Thus, the non-transitory, tangible computer readable medium, is adapted to store information and is adapted to interact with a data processing facility or computer device to execute the program of any of the above mentioned embodiments and/or to perform the method of any of the above mentioned embodiments.

The computer readable medium or storage medium may be a built-in medium installed inside a computer device main body or a removable medium arranged so that it can be separated from the computer device main body. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The term memory hardware is a subset of the term computer-readable medium.

The described aspects and examples of the present disclosure are intended to be illustrative rather than restrictive, and are not intended to represent every aspect or example of the present disclosure. While the fundamental novel features of the disclosure as applied to various specific aspects thereof have been shown, described and pointed out, it will also be understood that various omissions, substitutions and changes in the form and details of the devices illustrated and in their operation, may be made by those skilled in the art without departing from the spirit of the disclosure. For example, it is expressly intended that all combinations of those elements and/or method steps which perform substantially the same function in substantially the same way to achieve the same results are within the scope of the disclosure. Moreover, it should be recognized that structures and/or elements and/or method steps shown and/or described in connection with any disclosed form or aspects of the disclosure may be incorporated in any other disclosed or described or suggested form or aspects as a general matter of design choice. Further, various modifications and variations can be made without departing from the spirit or scope of the disclosure as set forth in the following claims both literally and in equivalents recognized in law.

1. A method for using a digital twin to determine a health of a power converter, the digital twin comprising a plurality of state equations representing circuit components of the power converter and at least one associated value for each component, each state equation capable of representing the circuit components for a defined power converter topology and related variants, and a self-evolving monitoring function, the method comprising:
a. receiving a sensed value from one or more sensors, respectively, the one or more sensors comprises a voltage sensor and/or a current sensor for sensing voltage and/or current within the power converter, respectively;
b. defining at least one set of values for the components of the power converter in the digital twin using the self-evolving monitoring function;
c. determining, using the self-evolving monitoring function, digital twin voltage and/or current corresponding to the sensed voltage and/or current respectively based on each defined set of values;
d. comparing, using the self-evolving monitoring function, each determined digital twin voltage and/or current, with values obtained from corresponding sensors;
e. determining, using the self-evolving monitoring function, a difference between each determined digital twin voltage and/or current and values obtained from the corresponding sensors using adjustable model parameters of the self-evolving monitoring function;
f. outputting one of the at least one set of values as the health of the power converter when the determined difference is less than an adjustable threshold of the self-evolving monitoring function; and
g. repeating (b)-(f), when the determined difference is greater than the adjustable threshold using new at least one set of values for the components of the power converter in the digital twin until a condition is met, where the new at least one set of values are based on adjustable determination parameters of the self-evolving monitoring function.

2. The method of claim 1, wherein a subset the values in each set are randomly determined.

3. The method of claim 2, where certain values are calculated in each set.

4. The method of claim 1, wherein the received sensed values from the one or more sensors are compensated based on error detection to determine the values obtained from the corresponding sensors or the determined digital twin current and/or voltage are compensated based on error detection.

5. The method of claim 1, wherein the adjustable model parameters include summation weights used to add the determined digital twin voltage and the determined digital twin current, wherein the summation weights are individually adjustable based on error detection with respect to the one or more sensors.

6. The method of claim 1, wherein the adjustable determination parameters are individually adjustable based on error detection.

7. The method of claim 4, wherein the error detection comprises determining at least quantization error, DC offset error and synchronization error.

8. The method of claim 6, wherein the adjustable determination parameters include a learning rate and weights for local and global best.

9. The method of claim 1, wherein the adjustable threshold is set based on operating conditions for the power converter.

10. The method of claim 9, wherein the operating conditions comprise at least one of a maximum output voltage or maximum inductor current.

11. The method of claim 9, wherein the adjustable threshold is initialized during a calibration period.

12. The method of claim 1, wherein the circuit components include switches and inductors and the at least one set of values includes Resistanceₒₙ, inductance and inductor resistance, wherein the method comprises determining the Resistanceₒₙ and inductor resistance independently where the inductor resistance is predicted during inductor discharging and the Resistanceₒₙ is predicted during inductor charging.

13. The method of any claim 1, wherein the plurality of state equations and the self-evolving monitoring function are stored in a memory and executable by a processor embedded with a housing of the power converter, wherein the outputting comprising transmitting a packet to an external device.

14. The method of claim 13, wherein the outputting further comprises causing a display on the external device to display the health of the power converter.

15. The method of claim 14, wherein when the condition is met and the difference is still greater than the adjustable threshold, the packet includes one set of values with a smallest difference and the determined difference; otherwise, when the difference is smaller than the adjustable threshold, the packet includes the one set of values without the determined difference.

16. The method of claim 14, wherein the values for different component types in the one set of values are separately displayed on the display.

17. The method of claim 14, wherein (b)-(g) are repeated for each new sensed value from the one or more sensors in (a).

18. The method of claim 17, wherein the display shows a change in the values over time, respectively.

19. The method of claim 18, further comprising determining a fault condition based on the change in the value over time and displaying indication based on the determination.

20. The method of claim 1, wherein the power converter is a multi-phase boost converter.

21. A health monitoring system for a power converter comprising:
a. a memory configured to store a digital twin comprising a plurality of state equations representing circuit components of a power converter and at least one associated value for each component, each state equation capable of representing the circuit components for a defined power converter topology and related variants, and a self-evolving monitoring function having adjustable model parameters, adjustable threshold and adjustable determination parameters, the adjustable model parameters include weights for combining determined voltage and determined current, respectively, the adjustable determination parameters are used to determine sets of values for the components for predicting the voltage and current, respectively;
b. a voltage sensor configured to detect a voltage of the power converter;
c. a current sensor configured to detect a current within the power converter; and
d. a processor configured to:
i. receive the detected voltage from the voltage sensor and the detected current from the current sensor;
ii. define at least one set of values for the components of the power converter in the digital twin using the self-evolving monitoring function;
iii. determine, using the self-evolving monitoring function, digital twin voltage and current corresponding to the sensed voltage and current respectively, based on each defined set of values;
iv. compare, using the self-evolving monitoring function, each determined digital twin voltage and current, with values obtained from the corresponding sensors;
v. determine, using the self-evolving monitoring function, a difference between each determined digital twin voltage and current and values obtained from the corresponding sensors using the adjustable model parameters of the self-evolving monitoring function; and
vi. output one of the at least one set of values as the health of the power converter when the determined difference is less than the adjustable threshold of the self-evolving monitoring function,
wherein when the difference is greater than the adjustable threshold, the processor is configured to repeat ii-v, using new at least one set of values for the component of the power converter in the digital twin until a condition is met, where the new at least one set of values are based on the adjustable determination parameters of the self-evolving monitoring function.

22. The health monitoring system of claim 21, wherein the memory is on-board memory co-located with the power converter and the system further comprises a communication interface configured to transmit the one of the at least one set of values as the health of the power converter or a set of values having a smallest difference when the condition is met.
